(19) United States
(12) Patent Application Publication
(10) Pub. No.: US 2026/0227705 A1
(43) Pub. Date: Aug. 6, 2026

(54) OPTICAL PROXIMITY CORRECTION METHOD AND METHOD OF MANUFACTURING MASK BY USING THE SAME

(71) Applicant: SAMSUNG ELECTRONICS CO., LTD., Suwon-si (KR)

(72) Inventors: Wonjoo IM, Suwon-si (KR); Dongchul LEE, Suwon-si (KR); Jaeyoung CHOI, Suwon-si (KR); Jungkee CHOI, Suwon-si (KR)

(73) Assignee: SAMSUNG ELECTRONICS CO., LTD., Suwon-si (KR)

(21) Appl. No.: 19/301,443

(22) Filed: Aug. 15, 2025

(30) Foreign Application Priority Data
Feb. 3, 2025 (KR) 10-2025-0013290

(51) Int. Cl. G03F 7/00; G03F 1/36

(52) U.S. Cl. CPC G03F 7/70441; G03F 1/36

(57) ABSTRACT

Provided is an optical proximity correction (OPC) method including: receiving a design layout including a jumper via pattern connecting a first via pattern with a second via pattern, the first via pattern and the second via pattern each connecting different metal layers; setting the first via pattern as a hidden target that does not undergo OPC, setting the second via pattern as a real target that undergoes OPC, and performing first OPC; performing mask rule check (MRC) or optical rule check (ORC) on a result of the first OPC; setting the first via pattern as the real target that undergoes OPC, setting the second via pattern as the hidden target that does not undergo OPC, and performing second OPC; merging the result of the first OPC with a result of the second OPC; and performing the MRC or the ORC on a result of the merge.

### CROSS-REFERENCE TO RELATED APPLICATION

This application is based on and claims priority to Korean Patent Application No. 10-2025-0013290, filed on February 3, 2025, in the Korean Intellectual Property Office, the disclosure of which is incorporated by reference herein in its entirety.

### BACKGROUND

### 1. Field

The present disclosure relates to an optical proximity correction (OPC) method used for a mask pattern during the manufacture of a semiconductor device, and more particularly, to a sequential OPC method for improving the patterning quality of a jumper via connecting multiple vias, which connect different metal wiring layers, and a method of manufacturing a mask by using the sequential OPC method.

### 2. Description of Related Art

In a semiconductor process, photolithography using a mask may be performed to form a pattern in a semiconductor substrate, such as a wafer. A mask may be simply defined as a pattern transfer artifact, in which a pattern is formed of an opaque material on a transparent base material. In brief, in a mask manufacturing process, a desired circuit is planned, the layout of the desired circuit is designed, and design data obtained through OPC is delivered as mask tape-out (MTO) design data. Thereafter, mask data preparation (MDP) is performed based on the MTO design data and an exposure process and the like may be performed on a mask substrate.

### SUMMARY

Provided is an optical proximity correction (OPC) method for improving the patterning quality of a jumper via. Specifically, the present disclosure provides an OPC method for reducing or preventing mask rule check (MRC) violation, critical dimension (CD) targeting failure, resistance value deviation, or the like, which may occur during the patterning of a jumper via that connects separate vias.

Further provided is an electronic system including an image sensor having a structure capable of increasing sensitivity and efficiently controlling characteristics, such as dark current and a white spot phenomenon, in each of a plurality of pixels.

According to an aspect of the disclosure, an optical proximity correction (OPC) method include: receiving a design layout including a jumper via pattern connecting a first via pattern with a second via pattern, the first via pattern and the second via pattern each connecting different metal layers; setting the first via pattern as a hidden target that does not undergo OPC, setting the second via pattern as a real target that undergoes OPC, and performing first OPC; performing mask rule check (MRC) or optical rule check (ORC) on a result of the first OPC; setting the first via pattern as the real target that undergoes OPC, setting the second via pattern as the hidden target that does not undergo OPC, and performing second OPC; merging the result of the first OPC with a result of the second OPC; and performing the MRC or the ORC on a result of the merge.

According to an aspect of the disclosure, an optical proximity correction (OPC) method includes: receiving a design layout of a jumper via pattern to be formed on a substrate, wherein the substrate includes a plurality of metal wiring layers; identifying a first via pattern and a second via pattern, each connecting different metal wiring layers of the plurality of metal wiring layers, in the design layout; based on a distance between the first via pattern and the second via pattern being less than a first reference value and a critical dimension or a resistance value of the jumper via pattern being beyond a target range, selecting the first via pattern and the second via pattern as objects of sequential OPC; setting the first via pattern as a hidden target that does not undergo OPC, setting the second via pattern as a real target that undergoes OPC, and performing first OPC; setting the first via pattern as the real target, setting the second via pattern as the hidden target, and performing second OPC; generating a jumper via OPC pattern by merging a result of the first OPC with a result of the second OPC; and performing mask rule check (MRC) or optical rule check (ORC) on the jumper via OPC pattern.

According to an aspect of the disclosure, a method of manufacturing a mask includes: receiving a design layout including a jumper via pattern connecting a first via pattern with a second via pattern, the first via pattern and the second via pattern each connecting different metal layers; setting the first via pattern as a hidden target that does not undergo optical proximity correction (OPC), setting the second via pattern as a real target that undergoes OPC, and performing first OPC; performing mask rule check (MRC) or optical rule check (ORC) on a result of the first OPC; setting the first via pattern as the real target that undergoes OPC, setting the second via pattern as the hidden target that does not undergo OPC, and performing second OPC; merging the result of the first OPC with a result of the second OPC; performing the MRC or the ORC on a result of the merge; transferring data on a design layout corresponding to the result of the merge as mask tape-out (MTO) design data; preparing mask data based on the MTO design data; and exposing a mask substrate based on the mask data.

### BRIEF DESCRIPTION OF DRAWINGS

The above and other aspects and features of certain embodiments of the present disclosure will be more clearly understood from the following detailed description taken in conjunction with the accompanying drawings, in which:

FIG. 1 is a schematic flowchart of an optical proximity correction (OPC) method according to an embodiment;

FIG. 2 is a schematic block diagram illustrating first and second via patterns and a jumper via pattern, according to an embodiment;

FIGS. 3A, 3B, and 3C illustrate procedures for performing OPC, according to an embodiment;

FIGS. 4A and 4B illustrate procedures for performing mask rule check (MRC) and/or optical rule check (ORC) on a result of merging the results of the first and second OPC, according to an embodiment;

FIGS. 5A and 5B illustrate procedures for correcting and performing MRC and/or ORC on a result of the merge, according to an embodiment;

FIG. 6 is a schematic flowchart of an OPC method according to an embodiment;

FIGS. 7A and 7B illustrate procedures for identifying first and second via patterns, according to an embodiment; and

FIG. 8 is a schematic flowchart of a method of manufacturing a mask by using an OPC method, according to an embodiment.

### DETAILED DESCRIPTION

Hereinafter, one or more embodiments of the present disclosure are described in detail with reference to the accompanying drawings. In the drawings, like reference characters denote like elements, and redundant descriptions thereof will be omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element, wherein the indirect connection may include “connection via a wireless communication network”.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

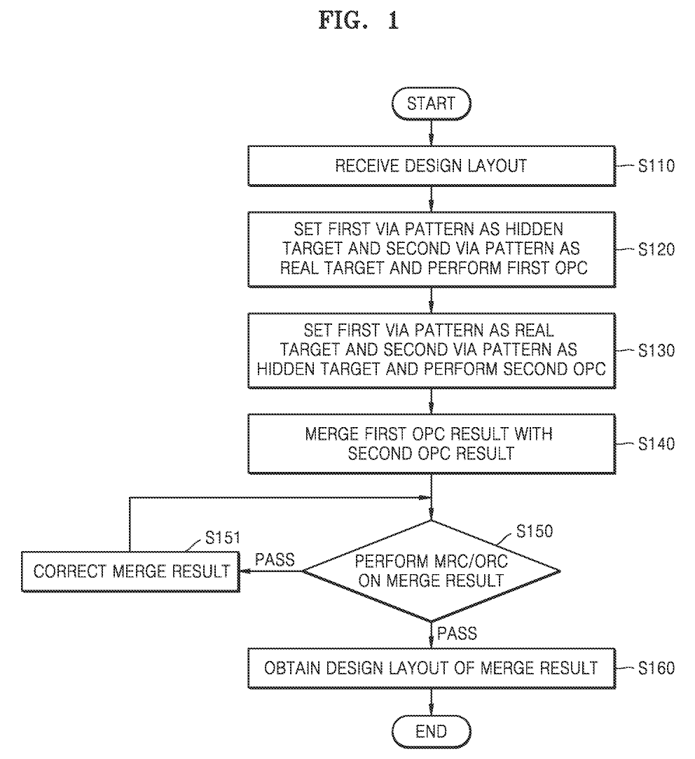

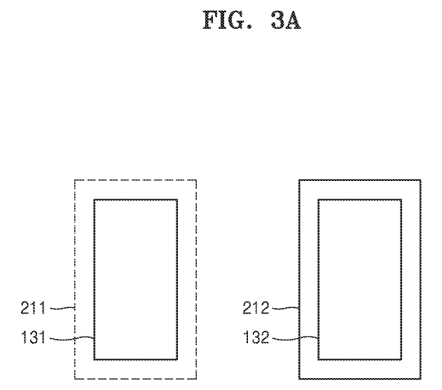

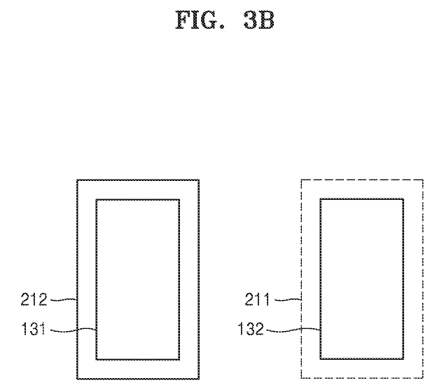

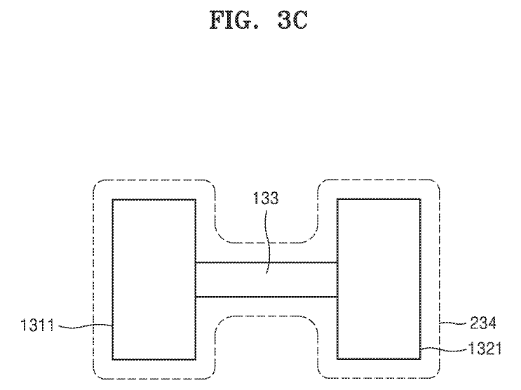

FIG. 1 is a schematic flowchart of an optical proximity correction (OPC) method according to an embodiment. An optical proximity effect refers to a pattern distortion occurring due to optical interaction between adjacent patterns during an exposure process. An optical proximity effect may occur in a jumper via pattern (e.g., 133 in FIG. 3) due to optical interference between a first via pattern (e.g., 131 in FIG. 3) and a second via pattern (e.g., 132 in FIG. 3).

Referring to FIG. 1, according to an embodiment, the OPC method may include receiving a design layout in operation S110, setting a first via pattern as a hidden target and a second via pattern as a real target and performing first OPC in operation S120, setting the first via pattern as a real target and the second via pattern as a hidden target and performing second OPC in operation S130, merging a result of the first OPC with a result of the second OPC in operation S140, performing mask rule check (MRC) and/or optical rule check (ORC) on a result of the merge in operation S150, correcting the result of the merge in operation S151 when the MRC and/or the ORC on the result of the merge fails, and obtaining a design layout of the result of the merge in operation S160.

Operation S110 of receiving the design layout is described in detail below. The design layout may refer to a layout of a pattern on a mask corresponding to a target pattern. Here, the target pattern may refer to a pattern to be formed on a semiconductor substrate such as a wafer. In other words, the target pattern may be formed by transferring a pattern on a mask onto a substrate through an exposure process. Because the pattern on a mask is projected and transferred in reduced size to a substrate, the size of the pattern on the mask may be greater than the size of the target pattern on the substrate.

The design layout may refer to the layout of a pattern on a mask in correspondence to the target pattern. Due to the nature of the exposure process, the shape of a target pattern on a wafer may be different from the shape of a pattern on a mask actually used in the exposure process. However, the shape of the initial design layout of the pattern on the mask may be substantially the same as the shape of the target pattern on the wafer.

In an embodiment, the target pattern may include a jumper via pattern which connects a first via pattern and a second via pattern, each connecting different metal wiring layers (e.g., metal wiring layers on, or embedded in, the substrate) to each other.

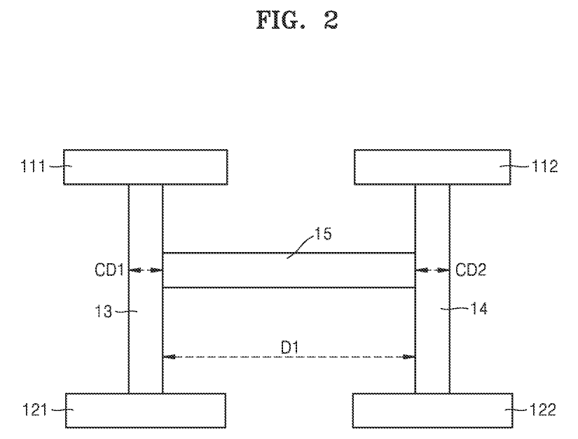

FIG. 2 is a schematic block diagram illustrating first and second via patterns and a jumper via pattern, according to an embodiment.

Referring to FIG. 2, a first via 13 may connect a first upper metal wiring 111 to a first lower metal wiring 121, a second via 14 may connect a second upper metal wiring 112 to a second lower metal wiring 122, and a jumper via 15 may connect the first via 13 to the second via 14.

Operation S120, of setting the first via pattern as the hidden target and the second via pattern as the real target and performing the first OPC, is described in detail below.

FIGS. 3A, 3B, and 3C illustrate procedures for performing OPC, according to an embodiment.

Referring to FIG. 3A, among a plurality of patterns of the design layout, a first via pattern 131 may be set as a hidden target 211 on which OPC is not performed, and a second via pattern 132 may be set as a real target 212 on which OPC is performed. Here, OPC may be performed only on the second via pattern 132, and the shape of the second via pattern 132 may be corrected.

The hidden target 211 may refer to a virtual dummy target on which OPC is not performed and may function as a reference pattern that is considered when an optical proximity effect is calculated but is excluded from real OPC calculation. In other words, the hidden target 211 may be said to be a pattern in a special state in which optical interaction is considered but shape correction is not performed.

As for the optical characteristics of the hidden target 211, the influence of scattered light is reflected on the calculation of an optical proximity effect, and the hidden target 211 participates in the generation of a diffraction pattern, but correction of the hidden target 211 is not performed during an actual pattern formation. Because calculation of the amount of shape correction for the hidden target 211 is excluded from an OPC engine, memory usage may be minimized, and an operation load may be reduced.

Contrarily, the real target 212 may refer to a target pattern in an active state in which OPC is actually performed, and shape correction may be performed on the real target 212 considering optical interaction between the real target 212 and surrounding patterns. Edge placement error (EPE) measurement and correction may be performed in real time with respect to the real target 212. As for the optical characteristics of the real target 212, a complete optical simulation is performed, every optical interaction with surrounding patterns is considered, and image formation under actual exposure conditions is predicted. In terms of calculation processing, OPC may be repeatedly performed, and an optical correction amount may be derived through EPE calculation for each segment.

Operation S130 of setting the first via pattern as the real target and the second via pattern as the hidden target and performing the second OPC is described in detail below. Referring to FIG. 3B, the first via pattern 131 may be set as the real target 212 on which OPC is performed, and the second via pattern 132 may be set as the hidden target 211 on which OPC is not performed. Here, OPC may be performed only on the first via pattern 131, and the shape of the first via pattern 131 may be corrected.

Transition between the hidden target 211 and the real target 212 may be very important in sequential OPC processes, that is, when operation S130 of performing the second OPC is performed after operation S120 of performing the first OPC. Transition from the hidden target 211 to the real target 212 may refer to the change of a state from a reference pattern into an active pattern. At this point, complete OPC may begin, and shape deformation may be tolerated. Contrarily, transition from the real target 212 to the hidden target 211 may refer to the change of a state from the active pattern into the reference pattern. At this point, OPC may stop, and a current shape may be fixed.

For example, in the first OPC (in operation S120), the first via pattern 131 may be set as the hidden target 211, and the shape of the first via pattern 131 may be fixed while the second via pattern 132 may be set as the real target 212 and may undergo shape correction. Contrarily, in the second OPC (in operation S130), the first via pattern 131 may transit to the real target 212 and undergo shape correction while the second via pattern 132 may transit to the hidden target 211, and the shape of the second via pattern 132 may be fixed.

In an actual implementation, there are detailed considerations for efficient processing of a hidden target and a real target. In the case of a hidden target, a target state flag may be added to a pattern data structure, shape information for optical calculation may be maintained, and unnecessary operation may be prevented through correction exclusion marking. For memory optimization, unnecessary data may be removed, and only minimum information for reference may be maintained so that calculation efficiency may be increased.

In the case of a real target, rules, such as segment length setting, curvature-based segmentation criteria, and shape deformation tolerance, may be applied for optimal segmentation. When a correction amount is calculated, an optical proximity effect model may be used, a correction table may be referred to, and calculation may be repeatedly performed according to defined criteria. Segmentation may refer to a process of dividing the edge of a pattern into small segments for OPC. Here, the edge of a first via OPC pattern 1311 and the edge of a second via OPC pattern 1321 may each be divided into a plurality of segments and may be corrected independently of each other.

The method of performing OPC while introducing the concepts of a hidden target and a real target and making sequential transition therebetween, according to the present disclosure, may efficiently increase the accuracy of the shape of a jumper via pattern and secure a process margin.

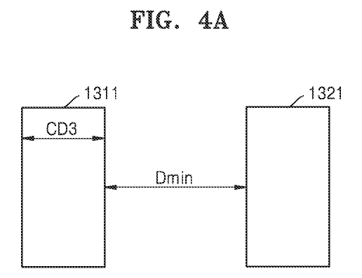

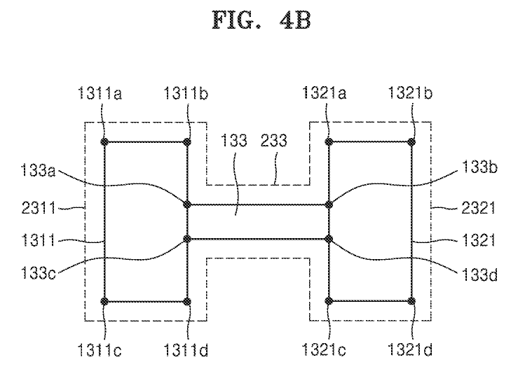

Operation S140 of merging the result of the first OPC with the result of the second OPC is described in detail below. Referring to FIG. 3C, the first via OPC pattern 1311 and the second via OPC pattern 1321 may be merged into a jumper via pattern 133. A result of the merge may be predicted through a simulation contour 234. The simulation contour 234 may represent a pattern shape on a wafer, the pattern shape being predicted through an OPC model. Here, the simulation contour may be expressed as a simulation contour 2311 (see FIG. 4B) of the first via OPC pattern 1311 and a simulation contour 2321 (see FIG. 4B) of the second via OPC pattern 1321.

Operation S150 of performing the MRC and/or the ORC on the result of the merge is described in detail below.

FIGS. 4A and 4B illustrate procedures for performing MRC and/or ORC on a result of merging the results of the first and second OPC, according to an embodiment.

Referring to FIG. 4A, the MRC may be performed on the first via OPC pattern 1311 and the second via OPC pattern 1321. The MRC may mean design rule verification in terms of mask manufacturability. Here, the MRC may verify whether the distance between the first via OPC pattern 1311 and the second via OPC pattern 1321 satisfies a reference minimum pattern distance Dmin.

Referring to FIG. 4B, the ORC may be performed on the simulation contour 2311 of the first via OPC pattern 1311, the simulation contour 2321 of the second via OPC pattern 1321, and a simulation contour 233 of the jumper via pattern 133. The ORC may mean pattern shape verification from an optical perspective and may evaluate the optical characteristics of a pattern predicted through the simulation contours 2311, 2321, and 233.

Here, EPE may be measured at first via EPE measurement points 1311a, 1311b, 1311c, and 1311d, second via EPE measurement points 1321a, 1321b, 1321c, and 1321d, and jumper via EPE measurement points 133a, 133b, 133c, and 133d. The EPE may refer to an edge position difference between a target pattern and a simulated pattern. The edge position difference may be measured at each of the EPE measurement points (1311a, 1311b, 1311c, 1321a, 1321b, 1321c, 1321d, 133a, 133b, 133c, and 133d) and may be used to evaluate the accuracy of OPC.

Operation S120 of setting the first via pattern as the hidden target and the second via pattern as the real target and performing the first OPC is described in detail below. Referring to FIG. 3A, among a plurality of patterns of the design layout, the first via pattern 131 may be set as the hidden target 211 on which OPC is not performed, and the second via pattern 132 may be set as the real target 212 on which OPC is performed.

Here, OPC of the second via pattern 132 may include a hammer head shape and a jog shape. Specifically, the upper and lower ends of the second via pattern 132 may have a hammer head shape, and the left and right sides of the second via pattern 132 may be divided into segments and may thus have a jog shape.

A hammer head may refer to a shape for widening an end portion of a line in order to prevent short-circuit of an end of the line. The hammer head shape may be applied to the upper and lower ends of each of the first and second via patterns 131 and 132.

A jog may refer to a fine correction structure formed in a stepped shape in a side surface of a pattern. Here, this correction may be applied to the left and right sides of a via pattern.

A segment may refer to a straight line corresponding to an edge of a design layout or data of the straight line. The edge of the design layout may be divided into multiple segments according to certain division rules. The length of the segment or the division rules may be set by a user executing the OPC method.

When OPC is performed on the second via pattern 132, a target pattern on a wafer may be different from an actual pattern on a mask, which is used in an exposure process, due to the characteristics of the exposure process. However, the shape of an initial design layout of the pattern on the mask may be substantially the same as the shape of the target pattern. OPC may refer to a method of correcting a design layout of patterns on a mask to suppress an optical proximity phenomenon from occurring due to influence between adjacent patterns with the miniaturization of patterns.

Operation S130 of setting the first via pattern as the real target and the second via pattern as the hidden target and performing the second OPC is described in detail below. Referring to FIG. 3B, the first via pattern 131 may be set as the real target 212 on which OPC is performed, and the second via pattern 132 may be set as the hidden target 211 on which OPC is not performed.

In operation S130 in which the first via pattern 131 is set as the real target, the second via pattern 132 is set as the hidden target, and the second OPC is performed, OPC may be performed on the first via pattern 131, which has been set as the hidden target and not undergone OPC in operation S120 of performing the first OPC before operation S130 of performing the second OPC. The OPC of the first via pattern 131 may be performed in the same manner as the OPC of the second via pattern 132, which has been described above. In other words, the upper and lower ends of the first via pattern 131 may each have a hammer head shape, and the left and right sides of the first via pattern 131 may each be divided into segments to have a jog shape.

Operation S140 of merging the result of the first OPC with the result of the second OPC is described in detail below. Referring to FIG. 3C, the first via OPC pattern 1311 and the second via OPC pattern 1321 may be merged into the jumper via pattern 133. The result of the merge may be predicted through the simulation contour 234. Here, the simulation contour 234 may be a result of a simulation using an OPC model and may correspond to the shape of the target pattern formed on the wafer in the exposure process using the mask.

Various basic data may be input to the OPC model as input data. The basic data may include data on an OPC pattern. The basic data may also include information data, such as the thickness, refractive index, and dielectric constant of photoresist, and data on a source map about the shape of an illumination system. The purpose of the OPC method may include making the simulation contour 234 as similar as possible to the shape of the target pattern.

Operation S150 of performing the MRC and/or the ORC on the result of the merge is described in detail below. Referring to FIG. 4A, the MRC may be performed on the first via OPC pattern 1311 and the second via OPC pattern 1321. The MRC may refer to a process of verifying whether the pattern on the mask satisfies certain rules, such as a minimum pattern distance and a minimum pattern size, which are required in manufacturing processes. For example, MRC may involve determining whether the distance between the first via OPC pattern 1311 and the second via OPC pattern 1321 satisfies a reference minimum pattern distance.

Referring to FIG. 4B, the ORC may be performed on the simulation contour 2311 of the first via OPC pattern 1311, the simulation contour 2321 of the second via OPC pattern 1321, and the simulation contour 233 of the jumper via pattern 133. The ORC may refer to a process of verifying whether the pattern on the mask satisfies rules required in optical processes.

To describe the EPE measurement in detail, EPE may be measured at the first via EPE measurement points 1311a, 1311b, 1311c, and 1311d, the second via EPE measurement points 1321a, 1321b, 1321c, and 1321d, and the jumper via EPE measurement points 133a, 133b, 133c, and 133d. The EPE may refer to a distance difference between a target image and a predicted image. An EPE value at each measurement point should be within an acceptable error range.

Operation S151 of correcting the result of the merge when the MRC and/or the ORC on the result of the merge fails is described in detail below.

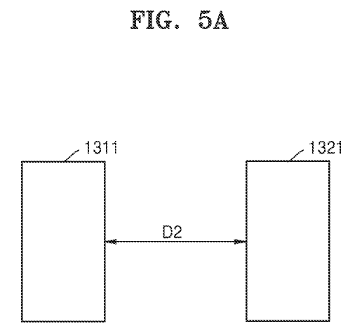

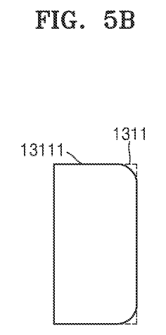

FIGS. 5A and 5B illustrate procedures for correcting and performing MRC and/or ORC on a result of the merge, according to an embodiment.

Referring to FIG. 5A, the case where a distance D2 between the first via OPC pattern 1311 and the second via OPC pattern 1321 does not satisfy an MRC reference value is shown. For example, FIG. 5A shows the case where the distance D2 is less than the reference minimum pattern distance.

Referring to FIG. 5B, to solve an MRC violation, a corrected first via OPC pattern 13111 may be generated by correcting the first via OPC pattern 1311. Specifically, the hammer head shape or jog shape of the first via OPC pattern 1311 may be modified such that the distance D2 between the first via OPC pattern 1311 and the second via OPC pattern 1321 satisfies the MRC reference value. For example, the hammer head size of the first via OPC pattern 1311 may be reduced, or the jog shape of the first via OPC pattern 1311 may be adjusted.

When the ORC is not satisfied, correction may be performed in a manner similar to that described above. When a violation of the optical rules occurs in a simulation contour, the optical rules may be satisfied by correcting a relevant portion of an OPC pattern. For example, when there is a measurement point at which an EPE value is beyond a tolerance limit, the corresponding portion of an OPC pattern may be modified such that the EPE value is within the tolerance limit.

The MRC and the ORC may be performed on the corrected OPC pattern. Such a correction and verification procedure may be repeatedly performed until all MRC and ORC rules are satisfied.

Operation S160 of obtaining the design layout of the result of the merge is described in detail below. A final OPC pattern that has passed the MRC and the ORC may be converted into a design layout for mask manufacturing. The design layout may have a graphical data format used in electronic design automation (EDA) software. For example, the design layout may be converted into a data format, such as Graphic Data System II (GDSII) or Open Artwork System Interchange Standard (OASIS).

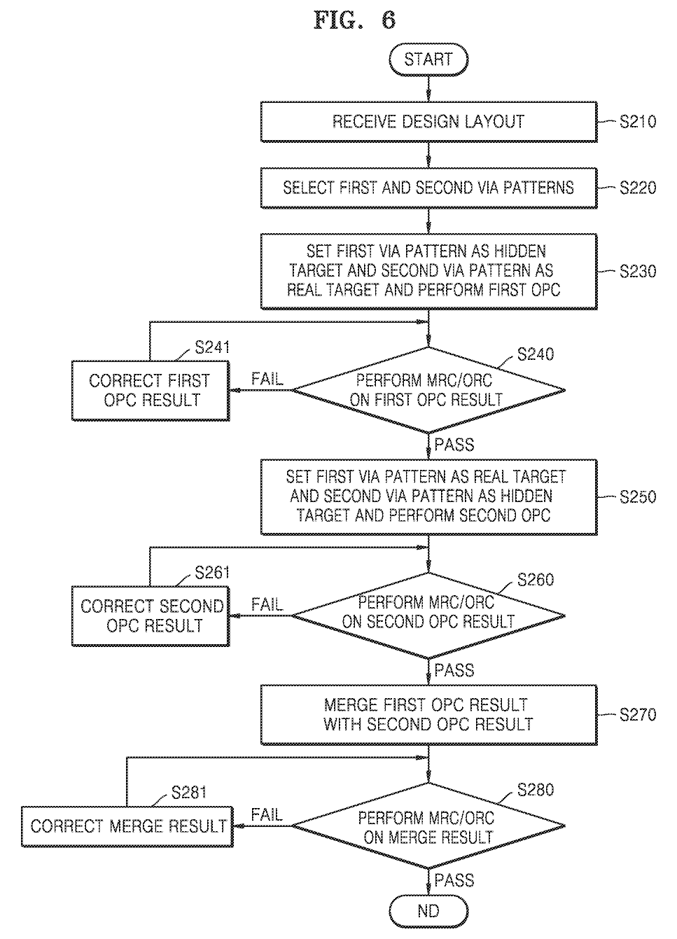

FIG. 6 is a schematic flowchart of an OPC method according to an embodiment. Unlike the OPC method described above, the OPC method of FIG. 6 may include selection of a first via pattern and a second via pattern, taking into account the distance between adjacent via patterns and the critical dimension (CD) of the via patterns, and individually performing an OPC and correction on each of the first and second via patterns.

Referring to FIG. 6, the OPC method may include receiving a design layout in operation S210, selecting first and second via patterns in operation S220, setting the first via pattern as a hidden target and the second via pattern as a real target and performing first OPC in operation S230, performing MRC and/or ORC on a result of the first OPC in operation S240, correcting the result of the first OPC in operation S241 when the result of the first OPC fails the MRC and/or ORC, setting the first via pattern as the real target and the second via pattern as the hidden target and performing second OPC in operation S250, performing MRC and/or ORC on a result of the second OPC in operation S260, correcting the result of the second OPC in operation S261 when the MRC and/or ORC on the result of the second OPC fails, merging the result of the first OPC with the result of the second OPC in operation S270, performing MRC and/or ORC on a result of the merge in operation S280, and correcting the result of the merge in operation S281 when the MRC and/or the ORC on the result of the merge fails.

In operation S220, the first via pattern and the second via pattern, which undergo sequential OPC, may be selected taking into account the distance between adjacent via patterns and the CD of the via patterns.

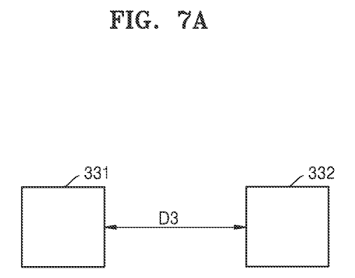

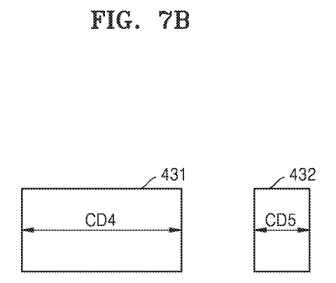

FIGS. 7A and 7B illustrate procedures for identifying first and second via patterns, according to an embodiment.

Referring to FIG. 7A, when a distance D3 between a first via pattern 331 and a second via pattern 332 is less than a minimum pattern distance reference value for an MRC or an ORC, the first via pattern 331 and the second via pattern 332 may be objects of sequential OPC. The minimum pattern distance reference value may be set considering the influence of an optical proximity effect in order to prevent a pattern from being deformed due to optical interaction between adjacent patterns in an exposure process.

Referring to FIG. 7B, when the CD of a jumper via pattern deviates from a target CD value, the jumper via pattern may be an object of sequential OPC. For example, when a critical dimension CD4 of a first via pattern 431 exceeds a target CD value or when a critical dimension CD5 of a second via pattern 432 is less than the target CD value, the first via pattern 431 and the second via pattern 432 may be selected. A CD deviation may be caused not only by an optical proximity effect but also by corrosion in a subsequent etching process, and accordingly, more precise OPC may be required for patterns of which the CD values are beyond a target range.

In operation S230 of performing the first OPC, OPC may be selectively performed on the selected patterns. Specifically, the first via pattern may be set as the hidden target on which OPC is not performed, and the second via pattern may be set as the real target on which OPC is performed. The OPC of hammer head and jog shapes may be performed on the second via pattern set as the real target. At this time, an OPC model may take into account the optical characteristics of exposure equipment, the properties of photoresist, process conditions, and the like.

Operation S270 of merging the result of the first OPC with the result of the second OPC is described in detail below. After individual correction and verification of each via pattern are completed through the OPC, a process of merging two OPC results into one jumper via pattern may be performed. This process may enable precise merging, considering the interaction between two patterns, rather than simply overlapping two patterns.

During the merge, the alignment and distance between via patterns may be adjusted based on the simulation contour of each of the via patterns. In particular, the shape of a hammer head or jog pattern may be finely adjusted such that the optical interaction between the via patterns is minimized in the boundary between the via patterns. This adjustment may be performed to prevent a bridge phenomenon or a pinch-off phenomenon from occurring in the boundary between the via patterns.

In operation S280 of performing the MRC and the ORC on the result of the merge, comprehensive verification may be performed on the entire jumper via pattern. In verification through the MRC, whether a merged pattern complies with the design rules of mask manufacturing processes may be checked. In particular, whether a fine pattern or a narrow spacing, which may occur in the connection between two via patterns, is beyond the limits of mask manufacturing processes may be mainly inspected.

In verification through the ORC, an optical simulation of the entire merged pattern may be performed. At this time, a simulation of an area that is wider than an individual pattern may be required. In particular, the influence of a proximity effect that may occur in the boundary between two via patterns may be precisely analyzed. Through the simulation, whether the shape of a predicted pattern satisfies design intent may be verified. In particular, whether disconnection or short-circuit occurs in the connection between two vias may be verified.

When the MRC or ORC rules are not satisfied, the result of the merge may be corrected in operation S281. In operation S281, a portion of an OPC pattern, which violates the rules, may be selectively corrected. For example, a relevant portion of the OPC pattern may be thinned when a bridge between two via patterns is predicted or may be thickened when a pinch is predicted. This correction procedure may be carefully performed to secure a process margin and maintain the connectivity and electrical characteristics of the entire jumper via pattern.

In particular, when an extreme ultraviolet (EUV) exposure process is used, more precise OPC may be required due to the short wavelengths of a light source. Because an edge slope is steep and a process window is narrow in an EUV process, careful attention may be required such that the shape of a merged pattern secures a sufficient process margin.

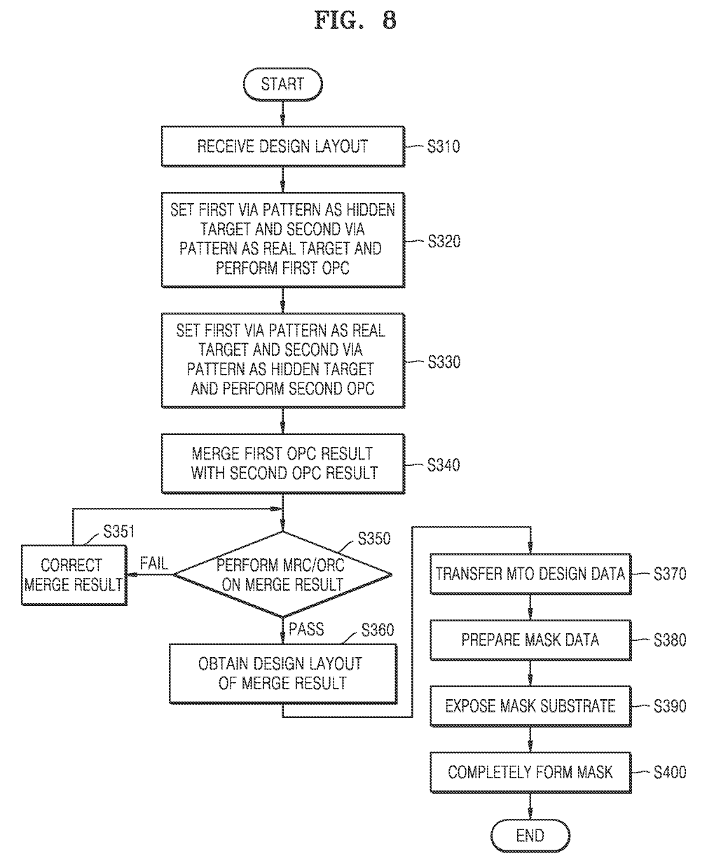

FIG. 8 is a schematic flowchart of a method of manufacturing a mask by using an OPC method, according to an embodiment. According to the embodiment of FIG. 8, the method of manufacturing a mask covers all processes from performing OPC to completing an actual mask. In particular, a method of manufacturing a mask suitable for an EUV exposure process is provided.

FIG. 1 is also referred to, and redundant descriptions given above with reference to FIGS. 1 to 7 are brief or omitted.

Referring to FIG. 8, the mask manufacturing method of the present embodiment may include receiving a design layout in operation S310, setting a first via pattern as a hidden target and a second via pattern as a real target and performing first OPC in operation S320, setting the first via pattern as a real target and the second via pattern as a hidden target and performing second OPC in operation S330, merging a result of the first OPC with a result of the second OPC in operation S340, performing MRC and/or ORC on a result of the merge in operation S350, correcting the result of the merge in operation S351 when the MRC and/or the ORC on the result of the merge fails, obtaining a design layout of the result of the merge in operation S360, transferring MTO design data in operation S370, preparing mask data in operation S380, exposing a mask substrate in operation S390, and completely forming a mask in operation S400.

In the mask manufacturing method of FIG. 8, an OPC method may correspond to, for example, the OPC method of FIG. 1. Specifically, operation S310 of receiving the design layout, operation S320 of setting the first via pattern as the hidden target and the second via pattern as the real target and performing the first OPC, operation S330 of setting the first via pattern as the real target and the second via pattern as the hidden target and performing the second OPC, operation S340 of merging the result of the first OPC with the result of the second OPC, operation S350 of performing the MRC and/or the ORC on the result of the merge, operation S351 of correcting the result of the merge when the MRC and/or the ORC on the result of the merge fails, and the operation S360 of obtaining the design layout of the result of the merge, which may respectively correspond to operation S110 of receiving the design layout, operation S120 of setting the first via pattern as the hidden target and the second via pattern as the real target and performing the first OPC, operation S130 of setting the first via pattern as the real target and the second via pattern as the hidden target and performing the second OPC, operation S140 of merging the result of the first OPC with the result of the second OPC, operation S150 of performing the MRC and/or the ORC on the result of the merge, operation S151 of correcting the result of the merge when the MRC and/or the ORC on the result of the merge fails, and the operation S160 of obtaining the design layout of the result of the merge in the OPC method of FIG. 1. Accordingly, detailed descriptions of operations S310 to S360 of the OPC method are omitted.

After the OPC method is performed, the MTO design data may be transferred to a mask manufacturing team in operation S370. In general, MTO may refer to handing over data on a mask pattern layout finally obtained through an OPC method to a mask manufacturing team and requesting mask manufacturing. Accordingly, in the mask manufacturing method of the present embodiment, the MTO design data may be substantially the same as data on an OPC layout obtained through the OPC method. The MTO design data may have a graphical data format used in EDA software. For example, the MTO design data may have a data format, such as GDSII or OASIS.

Thereafter, mask data preparation (MDP) may be performed in operation S380. The MDP may refer to a series of processes of processing the MTO design data to be used for actual mask manufacturing and may be performed in operation S380 in which a mask is manufactured. For example, the MDP may include format conversion referred to as fracturing, augmentation of a barcode for machine reading, a standard mask pattern for inspection, a job-deck, and/or the like, and automatic and manual verification. Here, the job-deck may refer to a text file containing a series of instructions for the placement of multiple mask files, a reference dose, and/or exposure speed or method.

The format conversion, i.e., fracturing, may refer to a process of dividing the MTO design data into areas and converting the MTO design data into a format for electron beam exposure equipment. For example, the fracturing may include data manipulations, such as scaling, data sizing, data rotation, pattern reflection, and color inversion. During the conversion through fracturing, data may be corrected for numerous systematic errors that may occur in a process of transferring design data to an image on a wafer.

The process of correcting data for systematic errors may be referred to as mask process correction (MPC) and may include, for example, line width adjustment called CD adjustment and a task for increasing the accuracy of pattern placement. Accordingly, the fracturing may contribute to an increase of the quality of a mask and may be performed in advance for the MPC. Here, the systematic errors may be caused by deformation occurring in an exposure process, a mask development and etching process, and a wafer imaging process.

The MDP may include MPC. As described above, the MPC may refer to a process of correcting an error, i.e., a systematic error, occurring in an exposure process. Here, the exposure process may be a concept that comprehensively including electron beam writing, development, etching, baking, and the like. Before the exposure process, data processing may be performed. The data processing may correspond to preprocessing of mask data and may include grammar check for the mask data and prediction of an exposure time.

After the mask data is prepared, the mask substrate may be exposed based on the mask data in operation S390. For example, the exposure may refer to electron beam writing. For example, the electron beam writing may be performed by way of gray writing using a multi-beam mask writer (MBMW). The electron beam writing may also be performed by a variable shaped beam (VSB) writer.

After the MDP, a process of converting the mask data into pixel data may be performed before the exposure process. The pixel data may be directly used in an actual exposure and may include data on a shape to be exposed and data on a dose allocated for the shape. Here, the data on the shape may include a bit-map data into which shape data, i.e., vector data, is converted through rasterization.

After the exposure process, a series of processes may be performed to completely form the mask in operation S400. For example, the series of processes may include a development process, an etching process, and a cleaning process. The series of processes may also include a measurement process, a defect detection process, or a defect repair process. Furthermore, the series of processes may also include a pellicle application process. Here, the pellicle application process may refer to a process of attaching a pellicle to the surface of the mask when it is confirmed through final cleaning and inspection that there are no contaminants or chemical stains so as to protect the mask from contamination during the delivery of the mask and the available lifetime of the mask.

While the present disclosure has been particularly shown and described with reference to embodiments thereof, it will be understood that various changes in form and details may be made therein without departing from the spirit and scope of the following claims.

What is claimed is:

1. An optical proximity correction (OPC) method comprising:
receiving a design layout comprising a jumper via pattern connecting a first via pattern with a second via pattern, the first via pattern and the second via pattern each connecting different metal layers;
setting the first via pattern as a hidden target that does not undergo OPC, setting the second via pattern as a real target that undergoes OPC, and performing first OPC;
performing mask rule check (MRC) or optical rule check (ORC) on a result of the first OPC;
setting the first via pattern as the real target that undergoes OPC, setting the second via pattern as the hidden target that does not undergo OPC, and performing second OPC;
merging the result of the first OPC with a result of the second OPC; and
performing the MRC or the ORC on a result of the merge.

2. The OPC method of claim 1, further comprising:
based on the result of the merge failing the MRC or the ORC, generating a corrected OPC pattern by correcting a portion of the result of the first OPC or a shape of the result of the second OPC; and
re-performing the MRC or the ORC on the corrected OPC pattern.

3. The OPC method of claim 1, further comprising:
after the receiving the design layout, checking whether a distance between adjacent via patterns, among patterns included in the design layout, exceeds an MRC reference value or an ORC reference value; and
based on the distance between the adjacent via patterns being less than the MRC reference value or the ORC reference value, selecting the adjacent via patterns as the first via pattern and the second via pattern.

4. The OPC method of claim 1, wherein the performing the first OPC and the performing the second OPC each comprises performing the OPC on a via pattern set as the real target without considering a via pattern set as the hidden target.

5. The OPC method of claim 1, wherein the performing the first OPC and the performing the second OPC each comprises correcting a shape of an OPC pattern such that a critical dimension of the jumper via pattern is within a certain target critical dimension range.

6. The OPC method of claim 1, wherein the performing the first OPC and the performing the second OPC each comprises correcting a shape of an OPC pattern such that a resistance value of the jumper via pattern is within a certain target resistance range.

7. The OPC method of claim 1, further comprising:
performing the MRC or the ORC on the result of the second OPC; and
based on the result of the first OPC or the result of the second OPC not satisfying the MRC or the ORC, correcting the result of the first OPC or the result of the second OPC and re-performing the MRC or the ORC on a result of the correction.

8. An optical proximity correction (OPC) method comprising:
receiving a design layout of a jumper via pattern to be formed on a substrate, wherein the substrate comprises a plurality of metal wiring layers;
identifying a first via pattern and a second via pattern, each connecting different metal wiring layers of the plurality of metal wiring layers, in the design layout;
based on a distance between the first via pattern and the second via pattern being less than a first reference value and a critical dimension or a resistance value of the jumper via pattern being beyond a target range, selecting the first via pattern and the second via pattern as objects of sequential OPC;
setting the first via pattern as a hidden target that does not undergo OPC, setting the second via pattern as a real target that undergoes OPC, and performing first OPC;
setting the first via pattern as the real target, setting the second via pattern as the hidden target, and performing second OPC;
generating a jumper via OPC pattern by merging a result of the first OPC with a result of the second OPC; and
performing mask rule check (MRC) or optical rule check (ORC) on the jumper via OPC pattern.

9. The OPC method of claim 8, wherein the first reference value is less than or equal to 1.2 times a minimum pattern distance defined in the MRC or the ORC.

10. The OPC method of claim 8, wherein the performing the first OPC comprises:
performing the MRC or the ORC on the result of the first OPC; and
based on the result of the first OPC not satisfying the MRC or the ORC, correcting a shape of the result of the first OPC.

11. The OPC method of claim 8, wherein the performing the second OPC comprises:
performing the MRC or the ORC on the result of the second OPC; and
based on the result of the second OPC not satisfying the MRC or the ORC, correcting a shape of the result of the second OPC.

12. The OPC method of claim 8, further comprising:
based on the jumper via OPC pattern not satisfying the MRC or the ORC, correcting a shape of the jumper via OPC pattern and re-performing the MRC or the ORC on a result of the correction.

13. The OPC method of claim 12, wherein the correcting the shape of the jumper via OPC pattern comprises adjusting the shape of the jumper via OPC pattern such that a wiring bridge is not formed between the first via pattern and the second via pattern.

14. The OPC method of claim 12, wherein the correcting the shape of the jumper via OPC pattern comprises adjusting the shape of the jumper via OPC pattern such that pinch-off does not occur between the jumper via OPC pattern and another pattern near the jumper via OPC pattern.

15. A method of manufacturing a mask, the method comprising:
receiving a design layout comprising a jumper via pattern connecting a first via pattern with a second via pattern, the first via pattern and the second via pattern each connecting different metal layers;
setting the first via pattern as a hidden target that does not undergo optical proximity correction (OPC), setting the second via pattern as a real target that undergoes OPC, and performing first OPC;
performing mask rule check (MRC) or optical rule check (ORC) on a result of the first OPC;
setting the first via pattern as the real target that undergoes OPC, setting the second via pattern as the hidden target that does not undergo OPC, and performing second OPC;
merging the result of the first OPC with a result of the second OPC;
performing the MRC or the ORC on a result of the merge;
transferring data on a design layout corresponding to the result of the merge as mask tape-out (MTO) design data;
preparing mask data based on the MTO design data; and
exposing a mask substrate based on the mask data.

16. The method of claim 15, wherein the performing the second OPC comprises performing the MRC or the ORC on the result of the second OPC.

17. The method of claim 16, further comprising:
based on the result of the first OPC not satisfying the MRC or the ORC, generating a corrected first OPC pattern by correcting a shape of the result of the first OPC; and
re-performing the MRC or the ORC on the corrected first OPC pattern.

18. The method of claim 15, wherein the performing the second OPC comprises performing the MRC or the ORC on the result of the second OPC.

19. The method of claim 18, further comprising:
based on the result of the second OPC not satisfying the MRC or the ORC, generating a corrected second OPC pattern by correcting a shape of the result of the second OPC; and
re-performing the MRC or the ORC on the corrected second OPC pattern.

20. The method of claim 15, further comprising:
based on the MRC or the ORC on the result of the merge failing, generating a corrected OPC pattern by correcting a portion of the result of the first OPC or a shape of the result of the second OPC; and
re-performing the MRC or the ORC on the corrected OPC pattern.
